(19) United States
(12) Patent Application Publication
(10) Pub. No.: US 2010/0119958 A1
(43) Pub. Date: May 13, 2010

(54) MASK BLANK, MASK FORMED FROM THE BLANK, AND METHOD OF FORMING A MASK

(75) Inventors: Chue San YOO, Hsin-Chu (TW); Chien-Chao HUANG, Hsin-Chu City (TW); Cheng-Ming LIN, Siluo Township (TW); Chai-Wei CHANG, Taipei City (TW); Jong-Yuh CHANG, Jhubei City (TW)

Correspondence Address: DUANE MORRIS LLP (TSMC);IP DEPARTMENT, 30 SOUTH 17TH STREET, PHILADELPHIA, PA, 19103-4196, US

(73) Assignee: TAIWAN SEMICONDUCTOR MANUFACTURING CO., LTD., Hsin-Chu (TW)

(21) Appl. No.: 12/268,598

(22) Filed: Nov. 11, 2008

(51) Int. Cl. G03F 1/00

(52) U.S. Cl. 430/5

(57) ABSTRACT

A mask for manufacturing a semiconductor device comprises a transparent substrate. A metal-containing layer overlies the transparent substrate in a first region. A capping layer overlies and is coextensive with the metal-containing layer without wrapping around side edges of the metal-containing layer. The capping layer is substantially free of nitride. The transparent substrate has a second region separate from the first region. The transparent substrate is exposed in the second region.

### FIELD OF THE INVENTION

The present invention relates to masks and mask blanks for semiconductor fabrication processes.

### BACKGROUND

Decreases in integrated circuit (IC) device dimensions are accompanied by decreases in dimensions of circuit pattern elements which connect the IC devices. If the wavelength of coherent light employed in a photolithographic fabrication process is not substantially smaller than the minimum dimension within the reticle through which those integrated circuit devices and conductor elements are printed, the resolution, exposure latitude and depth of focus of the printed device or element decreases. This is due to aberrational effects of coherent light passing through openings of width similar to the wavelength of the coherent light.

Phase shift masks (PSMs) have been used in projection lithography systems to expose a layer of photoresist formed on a semiconductor substrate as the requirements of image definition and depth of focus have become more stringent.

PSMs typically incorporate an additional layer, usually patterned, within the conventional chrome metal-on-glass reticle construction. The additional layer, which is commonly referred to as a shifter layer, has a thickness related to the wavelength of coherent light passing through the PSM. Coherent light rays passing through the transparent substrate and the shifter layer have different optical path lengths and thus emerge from those surfaces with different phases. The interference effects of the coherent light rays of different phase provided by a Phase Shift Mask (PSM) form a higher resolution image when projected onto a semiconductor substrate.

U.S. Pat. No. 5,045,417 describes a PSM as shown in FIG. 1 of the present disclosure. The mask has light shield regions, A and transmission regions B for transferring a given pattern at least by irradiation of coherent light locally. A transparent film 4a is formed above a substrate 2 in a pattern slightly wider than that of the pattern of metal layer 3. Thus, a phase shifting portion 4a is formed in a part of the transmission region B for shifting a phase of transmitted light. A phase contrast is generated between the light transmitted through the phase shifting portion 4a and the light transmitted through the remaining portion 5 of transmission region B where the phase shifting portion 4a is not formed. The phase shifting portion 4a is arranged so that the interfering light is weakened in the boundary area of the transmission region B and light shield region A.

### SUMMARY OF THE INVENTION

In some embodiments, a mask for manufacturing a semiconductor device comprises a transparent substrate. A metal-containing layer overlies the transparent substrate in a first region. A capping layer overlies and is coextensive with the metal-containing layer without wrapping around side edges of the metal-containing layer. The capping layer is substantially free of nitride. The transparent substrate has a second region separate from the first region. The transparent substrate is exposed in the second region.

In some embodiments, a mask blank for manufacturing a semiconductor mask or reticle comprises a transparent substrate. A metal layer overlies the transparent substrate. A planar capping layer overlies the metal layer without wrapping around side edges thereof. The capping layer is substantially free of nitride.

In some embodiments, a method of forming a mask comprises forming a metal-containing layer above a transparent substrate in a first region on a first surface of the transparent substrate. A capping layer is formed overlying and coextensive with the metal-containing layer, such that the capping layer is substantially free of nitride. The first surface of the transparent substrate is exposed in a second region separate from the first region, so that the metal-containing layer includes at least two patterns in the first region, with the second region occupying an entire distance between the at least two patterns, and the second region is free of the capping layer.

### BRIEF DESCRIPTION OF THE DRAWINGS

FIG. 1 is a cross section of a prior art phase shift mask.

FIG. 2A is a cross section of an example of a phase shift mask blank.

FIG. 2B is a cross section of a phase shift mask formed from the blank of FIG. 2A.

FIG. 3A is a cross section of an example of a binary mask blank.

FIG. 3B is a cross section of a binary mask formed from the blank of FIG. 3A.

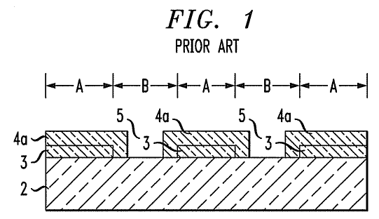

### DETAILED DESCRIPTION

This description of the exemplary embodiments is intended to be read in connection with the accompanying drawings, which are to be considered part of the entire written description. In the description, relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation.

The inventors have determined that phase shift masks (PSMs) are subject to a mask haze problem. Haze is a complicated precipitate, induced by ammonia, sulfured ion components and the like. Two common ways to address the mask haze problems are: to use less chemical mask cleaning; and chemical controlled mask storage with N₂ gas purge.

However, in a PSM including a nitride material in the transparent layer of the mask blank (overlying the metal regions), the inclusion of nitrogen in the mask blank film can generate ammonia to induce haze problems. From the composition of a transparent layer, the PSM may include a large amount of nitrogen capable of serving as a source of ammonia NH₄+ after exposure to light from an ArF excimer laser light source (wavelength: 193 nm).

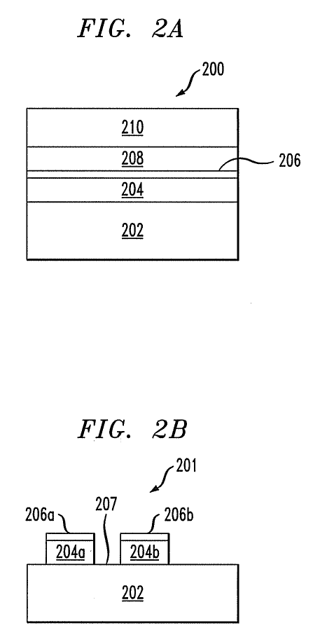

FIG. 2A is a cross sectional diagram of a phase shift mask blank 200 for manufacturing a phase shift mask (PSM) 201 (shown in FIG. 2B) for a semiconductor device. In some embodiments, as shown in FIG. 2A, a mask blank 200 for manufacturing a semiconductor mask or reticle comprises: a transparent substrate 202; a metal layer 204 overlying the transparent substrate 202; and a planar capping layer 206 overlying the metal layer 204 without wrapping around side edges thereof, wherein the capping layer 206 is substantially free of nitride.

By providing a capping layer 206 without nitrogen on the PSM blank 200, a substantial ammonia generator is eliminated as a source of haze.

The mask blank 200 comprises a transparent substrate 202, formed of a material such as a quartz, CaF₂ or other material that is transparent to the exposure light.

A metal-containing phase shift layer 204 is formed overlying the transparent substrate 202. In some embodiments, the metal of which the phase shift function film 204 is constructed may include any element selected from among transition metals, lanthanoids and combinations thereof. Examples include, Mo, Zr, Ta, Cr and Hf. In more specific examples, metal containing layer 204 may be a material such as MoSi, ToSi₂, iron oxide, inorganic material, Mo, Nb₂O₅, Ti, Ta, CrN, MoO₃, MoN, Cr₂O₃, TiN, ZrN, TiO₂, TaN, Ta₂O₅, SiO₂, NbN, Si₃N₄, ZrN, Al₂O₃N, or combinations thereof. In one example, the metal containing layer is formed of either MoSi, MoSiON or Cr.

The metal-containing layer 204 may be about 700 Å thick for technology nodes beyond 0.13 μm technology, for example, but other thicknesses may be used as appropriate for various other technology nodes. For example, the thickness of metal-containing layer 204 may range from 400 to 1500 Å thick.

A capping layer 206 is formed overlying and coextensive with the metal-containing layer 204, without wrapping around side edges thereof. The capping layer 206 is substantially free of nitride. In some embodiments, the capping layer 206 is an oxide, such as SiO or SiO₂. The capping layer 206 may be about 50 Å thick, for example.

In some embodiments, as shown in FIG. 2A, the phase shift mask blank 200 further includes a second metal containing layer 208 formed on the capping layer 206. The second metal containing layer 208 may comprise Cr, for example. The second metal containing layer 208 may be a chromium-based light shielding or antireflection film 208 formed on the capping layer 206 for reducing reflection from the metal film 204. The chromium-based light-shielding film or chromium-based antireflection film 208 may be made of chromium oxycarbide (CrOC), chromium oxynitride carbide (CrONC) or a multilayer combination of both. The second metal containing layer 210 may be about 590 Å thick, for example.

In some embodiments, the film 208 is a CrOC film consisting essentially of 20 to 95 at % Cr, 1 to 30 at % C and 1 to 60 at % O. In other embodiments, the film 208 is a CrONC film consisting essentially of 20 to 95 at % Cr, 1 to 20 at % C, 1 to 60 at % O, and 1 to 30 N.

The chromium-based light-shielding film or chromium-based antiroflection film 208 can be formed by reactive sputtering. For example, the target may be chromium or chromium having oxygen, nitrogen, carbon or a combination thereof added. The sputtering gas is an inert gas such as neon, argon or krypton to which a gas containing carbon, oxygen or nitrogen may be added, depending on the desired final composition of the layer 208.

A layer 210 of photoresist is formed on the second metal containing layer 208. A variety of photoresists may be used. For example, layer 210 may comprise NEB-22 negative photoresist sold by Sumitomo Chemical Co., Ltd., Tokyo, Japan, with a thickness of about 3000 Å. The photoresist is used during a photolithographic process for selectively etching material from the mask blank 200 to form the PSM 201 shown in FIG. 2B.

The layer 210 of photoresist may be applied by spin coating, for example, following deposition of the Cr layer 208. Alternatively, the photoresist 208 may be formed by chemical vapor deposition (CVD), physical vapor deposition (PVD), atomic layer deposition (ALD), remote plasma enhanced chemical vapor deposition (RPECVD), liquid source misted chemical deposition (LSMCD), coating, or another process that is adapted to form a thin film layer over the Cr layer 208.

In one embodiment of a PSM blank as shown in FIG. 2A, the substrate 202 comprises quartz, the metal containing layer 204 comprises MoSiON, the capping layer 206 comprises SiO₂, and the mask blank 200 further comprises a layer 208 of Cr overlying the capping layer 206. A layer 210 of NEB-22 photoresist is applied over the Cr layer 208. This is only one example, and any combination of the various constituent layers described above may be used.

FIG. 2B is a cross sectional diagram of an attenuated phase shift mask 201, made from PSM blank 200, for manufacturing a semiconductor device. The mask 201 comprises a transparent substrate 202, formed of a material such as a quartz, CaF₂ or other material that is transparent to the exposure light.

A metal-containing layer 204a, 204b is formed from the layer 204, overlying the transparent substrate 202 in a first region. In some embodiments, metal-containing layer 204a, 204b may include any element selected from among transition metals, lanthanoids and combinations thereof. Examples include, Mo, Zr, Ta, Cr and Hf. In more specific examples, metal containing layer 204 may be a material such as ToSi₂, iron oxide, inorganic material, Mo, Nb₂O₅, Ti, Ta, CrN, MoO₃, MoN, Cr₂O₃, TiN, ZrN, TiO₂, TaN, Ta₂O₅, SiO₂, NbN, Si₃N₄, ZrN, Al₂O₃N, or combinations thereof. In one example, the metal containing layer is formed of either MoSi, MoSiON or Cr.

A capping layer 206a, 206b is formed overlying and coextensive with the metal-containing layer 204a, 204b without wrapping around side edges thereof. The capping layer 206a, 206b is substantially free of nitride. In some embodiments, the capping layer is an oxide, such as SiO or SiO₂.

In some embodiments, the step of forming a capping layer 206 includes plasma vapor deposition. Preferably, the step of forming a capping layer 206 includes sputtering. For example, an SiO₂ target may be used for sputtering the capping layer 206.

The transparent substrate 202 has a second region 207 separate from the first region 204a, 204b. The transparent substrate 202 is exposed in the second region 207, without having the capping layer 206a or 206b extending over the second region. The second region 207 occupies an entire distance between the at least two patterns 204a, 204b. The second region 207 is also free of the capping layer 206a, 206b.

The resulting PSM 201 has a transparent substrate 202. A metal-containing layer 204a, 204b overlies the transparent substrate 202 in a first region. A capping layer 206a, 206b overlies and is coextensive with the metal-containing layer 204a, 204b without wrapping around side edges of the metal-containing layer. The capping layer 206a, 206b is substantially free of nitride. The transparent substrate 202 has a second region 207 separate from the first region containing metal layer 204a, 204b. The transparent substrate 202 is exposed in the second region 207.

In one example, the transparent substrate 202 is quartz, the phase shifting regions 204a, 204b are MoSiON, and the capping layer is SiO₂. Samples of a PSM 201 as shown in FIG. 2B were fabricated, and the yield was compared with that of standard (STD) masks formed with a nitride capping layer over the phase shifting layer thereof. The process capability index Cp for the mask having a capping layer without nitride compares favorably to that of a mask formed with a nitride capping layer, as shown in Table 1.

TABLE 1
Cp Yield

| | |
|---|---|
| STD | 71.03 |
| Mask w/o nitride | 72.01 |
| in capping layer | |
| Bias | 0.98 |

A sample was tested and haze check performed by 172 nm vacuum ultra violet (VUV) exposure. The PSM 201 having the capping layer 206a, 206b without nitride was exposed to the 172 nm light for 15 minutes. A subsequent scanning electron microscope inspection showed no noticeable haze defects.

FIG. 4 shows a process apparatus for depositing the layers 204, 206, 208 on the substrate 202. The metal-containing layer 204 may be formed by sputtering, as described below with reference to apparatus 400 shown in FIG. 4. The substrate 202 and a target (or targets) 404 in a chamber 406, feeding a sputtering gas 408 or gases to the chamber 406, and applying power to the target 404 to create a discharge for depositing a film 204 on the substrate 202. The sputtering gas 408 may be an inert gas such as neon, argon or krypton, optionally mixed with a reactive gas which such as oxygen-containing gases, nitrogen-containing gases or carbon-containing gases, depending on the desired type of light elements including oxygen, nitrogen and carbon, of which the metal-containing phase shift layer 204 is formed.

For example, the target or targets 404 may contain molybdenum and silicon, and the sputtering gas 408 may include an inert gas plus oxygen and nitrogen. The target(s) 404 contains a metal (corresponding to the metal contained in the metal-containing phase shift layer 204 to be formed) and/or silicon. The metal element (e.g., Mo) and silicon may be formed using a metal target and a silicon target separate from each other, or a metal silicide (e.g., MoSi) target and a silicon target, or a metal silicide (e.g., MoSi) target alone. Similarly, in place of an Mo target, an alloy target including an additional metal may optionally be used. Alternatively, two separate metal targets and a silicon target may be used. In other embodiments, the oxygen for forming MoSiON may be provided using an SiO₂ target.

In one embodiment, the sputtering gas 408 is argon. When only an inert gas is used as the sputtering gas 408, a metal containing layer 204 composed of a metal and silicon (e.g., MoSi) can be formed.

In one embodiment, the capping layer is applied using an Si or SiO₂ target, a sputtering gas containing O₂ and Ar gas, and RF power of 500 to 1000 W.

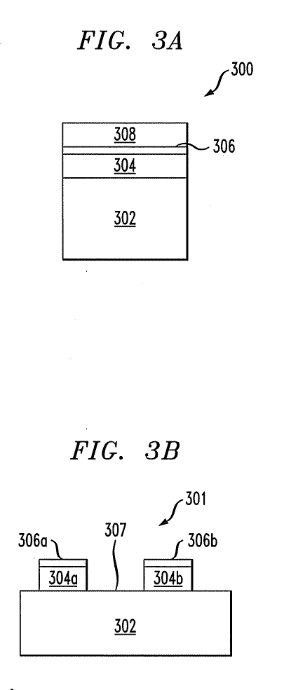

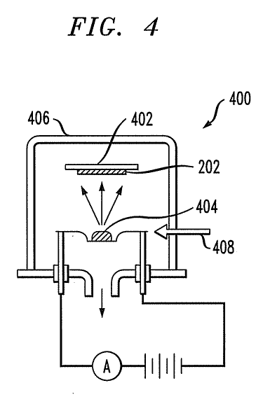

FIG. 3 is a cross section of a binary mask blank 300 according to another embodiment. The binary mask blank 300 comprises a transparent substrate 302; a metal layer 304 overlying the transparent substrate 302; and a planar capping layer 306 overlying the metal layer 304 without wrapping around side edges thereof, wherein the capping layer 306 is substantially free of nitride. A layer of photoresist 308 is formed over the capping layer 306. The capping layer 306 can also prevent haze formation in a binary mask blank 300, in a manner analogous to haze prevention in the PSM described above.

The mask blank 300 is used to malce a mask 301 (FIG. 3B). In some embodiments, mask 301 is an extreme ultraviolet mask. The mask blank 300 comprises a transparent substrate 302, formed of a material such as a quartz, CaF₂ or other material that is transparent to the exposure light.

A metal-containing phase shift layer 304 is formed overlying the transparent substrate 302. In some embodiments, the metal of which the phase shift function film 204 is constructed may include any element selected from among transition metals, lanthanoids and combinations thereof. Examples include, Mo, Zr, Ta, Cr and Hf. In more specific examples, metal containing layer 304 may be a material such as MoSi, ToSi₂, iron oxide, inorganic material, Mo, Nb₂O₅, Ti, Ta, CrN, MoO₃, MoN, Cr₂O₃, TiN, ZrN, TiO₂, TaN, Ta₂O₅, SiO₂, NbN, Si₃N₄, ZrN, Al₂O₃N, or combinations thereof. In one example, the metal containing layer comprises Cr.

The metal-containing layer 304 may be about 700 Å thick, for example, but other thicknesses may be used as appropriate for various other technology nodes. For example, the thickness of metal-containing layer 304 may range from 400 to 1500 Å thick.

A capping layer 306 is formed overlying and coextensive with the metal-containing layer 304, without wrapping around side edges thereof. The capping layer 306 is substantially free of nitride. In some embodiments, the capping layer 306 is an oxide, such as SiO or SiO₂. The capping layer 306 may be about 50 Å thick, for example.

A layer 308 of photoresist is formed on the capping layer 306. A variety of photoresists may be used. For example, layer 308 may comprise NEB-22 negative photoresist, with a thickness of about 3000 Å. The photoresist 308 is used during a photolithographic process for selectively etching material from the mask blank 300 to form the mask 301 shown in FIG. 3B.

FIG. 3B shows the completed binary mask 301, formed from the blank 300 by photo-patterning the photoresist layer 308 and removing the undesired patterns. The binary mask 301 has a transparent substrate 302; a metal layer 304a, 304b overlying the transparent substrate 302 in a first region; and a planar capping layer 306a, 306b overlying the metal layer 304a, 304b without wrapping around side edges thereof. The capping layer 306a, 306b is substantially free of nitride. The top surface of the transparent substrate 302 is exposed in a second region 307 separate from the first region containing the metal layer patterns 304a, 304b, so that the metal-containing layer includes at least two patterns 304a, 304b in the first region, with the second region 307 occupying an entire distance between the at least two patterns 304a, 304b, and the second region 307 is free of the capping layer 306a, 306b. The capping layer 306a, 306b can also prevent haze formation in a binary mask 301, in a manner analogous to haze prevention in the PSM described above.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A mask for manufacturing a semiconductor device comprising:
a transparent substrate;
a metal-containing layer overlying the transparent substrate in a first region; and
a capping layer overlying and coextensive with the metal-containing layer without wrapping around side edges thereof, wherein the capping layer is substantially free of nitride,
the transparent substrate having a second region separate from the first region, wherein the transparent substrate is exposed in the second region.

2. The mask of claim 1, wherein the capping layer comprises an oxide.

3. The mask of claim 2, wherein the capping layer comprises SiO₂.

4. The mask of claim 1, wherein the metal-containing layer includes at least two patterns in the first region, with the second region occupying an entire distance between the at least two patterns, the second region being free of the capping layer.

5. The mask of claim 1, wherein the substrate comprises quartz.

6. The mask of claim 1, wherein the metal containing layer comprises one of the group consisting of MoSiON and Cr.

7. The mask of claim 1, wherein the mask is an extreme ultraviolet mask.

8. A mask blank for manufacturing a semiconductor mask or reticle comprising:
a transparent substrate;
a metal layer overlying the transparent substrate; and
a planar capping layer overlying the metal layer without wrapping around side edges thereof, wherein the capping layer is substantially free of nitride.

9. The mask blank of claim 8, wherein the capping layer comprises an oxide.

10. The mask blank of claim 8, wherein the capping layer comprises SiO₂.

11. The mask blank of claim 8, wherein the metal containing layer comprises one of the group consisting of MoSiON and Cr.

12 The mask blank of claim 8, further comprising a second metal-containing layer overlying the capping layer.

13. The mask blank of claim 12, wherein the metal containing layer comprises MoSiON and the second metal-containing layer comprises Cr.

14. The mask blank of claim 8, wherein:
the substrate comprises quartz,
the metal containing layer comprises MoSiON,
the capping layer comprises SiO₂, and
the mask blank further comprises a layer of Cr overlying the capping layer.

15. A method of forming a mask, comprising:
forming a metal-containing layer above a transparent substrate in a first region on a first surface of the transparent substrate;
forming a capping layer overlying and coextensive with the metal-containing layer, such that the capping layer is substantially free of nitride; and
exposing the first surface of the transparent substrate in a second region separate from the first region, so that the metal-containing layer includes at least two patterns in the first region, with the second region occupying an entire distance between the at least two patterns, and the second region is free of the capping layer.

16. The method of claim 15, wherein the capping layer comprises SiO₂.

17. The method of claim 15, wherein the step of forming a capping layer includes plasma vapor deposition.

18. The method of claim 15, wherein the step of forming a capping layer includes sputtering.

19. The method of claim 18, wherein the sputtering is performed using a target comprising Si or SiO₂.

20. The method of claim 19, wherein the sputtering is performed with a sputtering gas comprising O₂ and Ar.
